(19) United States
(12) Patent Application Publication
(10) Pub. No.: US 2007/0119499 A1
(43) Pub. Date: May 31, 2007

(54) Solar cell

(75) Inventors: Byong-Cheol Shin, Yongin-si (KR); Ji-Won Lee, Yongin-si (KR); Wha-Sup Lee, Yongin-si (KR); Kwang-Soon Ahn, Yongin-si (KR); Jae-Man Choi, Yongin-si (KR); Joung-Won Park, Yongin-si (KR)

Correspondence Address: STEIN, MCEWEN & BUI, LLP, 1400 EYE STREET, NW, SUITE 300, WASHINGTON, DC, 20005, US

(73) Assignee: Samsung SDI Co., Ltd., Suwon-si (KR)

(21) Appl. No.: 11/593,572

(22) Filed: Nov. 7, 2006

(30) Foreign Application Priority Data
Nov. 30, 2005 (KR) 2005-0115549

(51) Int. Cl. H01L 31/00

(52) U.S. Cl. 136/263

(57) ABSTRACT

A solar cell includes first and second electrodes facing each other, a light absorption layer formed on the first electrode, and a lead electrode formed on the first electrode in a first direction such that the lead electrode is spaced apart from the light absorption layer. When the length of a first edge of the light absorption layer proceeding in the first direction is indicated by A and the length of a second edge of the light absorption layer proceeding in a second direction crossing the first direction is indicated by B, the value of A/B satisfies the following condition:
1.3≦A/B≦125.

### CROSS-REFERENCE TO RELATED APPLICATION

This application claims priority to and the benefit of Korean Patent Application No. 2005-115549 filed in the Korean Intellectual Property Office on Nov. 30, 2005, the entire disclosure of which is incorporated herein by reference.

### BACKGROUND OF THE INVENTION

1. Field of the Invention

Aspects of the present invention relate to a solar cell, and in particular, to a solar cell with high energy efficiency.

2. Description of the Related Art

Generally, a solar cell generates electrical energy using solar energy, an unlimited energy source, in an environmentally friendly way. Typical solar cells include silicon solar cells, dye-sensitized solar cells, etc.

The dye-sensitized solar cell has excellent photoelectric conversion efficiency, a lower production cost, and flexible processing, compared to the silicon solar cell. Furthermore, since the dye-sensitized solar cell has transparent electrodes, it may be used in constructing outer walls for buildings or greenhouses.

However, since the photoelectric conversion efficiency of solar cells is not high, solar cells are not yet in widespread use. Many studies have been undertaken in order to enhance the photoelectric conversion efficiency of solar cells, but most of the studies have been limited to the field of development of new dyes. In this regard, it is desirable to develop a new technology for enhancing the photoelectric conversion efficiency of the solar cell.

### SUMMARY OF THE INVENTION

Aspects of the present invention provide a solar cell that has a light absorption layer with an optimized design for serving to generate excited electrons.

According to one aspect of the present invention, the solar cell includes first and second electrodes facing each other, a light absorption layer formed on the first electrode, and a lead electrode formed on the first electrode in a first direction such that the lead electrode is spaced apart from the light absorption layer. The light absorption layer has a first edge proceeding in a first direction and a second edge proceeding in a second direction crossing the first direction. When the length of the first edge of the light absorption layer proceeding in the first direction is indicated by A and the length of the second edge of the light absorption layer proceeding in the second direction crossing the first direction is indicated by B, the value of A/B satisfies the following condition:
1.3≦A/B≦125

The value of A/B more preferably satisfies the following condition:
1.3≦A/B≦5

When the area ratio of the light absorption layer to the first electrode is indicated by C, the value of C satisfies the following condition:
0.05≦C≦1

The lead electrode may be placed close to an edge of the first electrode. It is preferable that the lead electrode is placed close to a long edge of the first electrode. An edge of the first electrode proceeding in the first direction may be longer than an edge of the first electrode proceeding in the second direction, and an edge of the second electrode proceeding in the first direction may be longer than an edge of the second electrode proceeding in the second direction. Another lead electrode may be formed on the second electrode in the first direction.

The light absorption layer may be formed with a dye-adsorbed porous film. That is, the solar cell may be a dye-sensitized solar cell.

According to another aspect of the present invention, a solar cell comprises first and second electrodes facing each other, a light absorption layer formed on the first electrode, and a lead electrode formed on the first electrode in a first direction such that the lead electrode is spaced apart from the light absorption layer, wherein when the greatest length of the light absorption layer in a direction parallel to the first direction of the lead electrode is indicated by D and the greatest length of the light absorption layer in the second direction orthogonal to the first direction is indicated by E, the value of D/E satisfies the following condition:
1.3≦D/E≦125

Additional aspects and/or advantages of the invention will be set forth in part in the description which follows and, in part, will be obvious from the description, or may be learned by practice of the invention.

### BRIEF DESCRIPTION OF THE DRAWINGS

These and/or other aspects and advantages of the invention will become apparent and more readily appreciated from the following description of the embodiments, taken in conjunction with the accompanying drawings of which:

FIG. 1 is a plan view of a solar cell according to an embodiment of the present invention;

FIG. 2 is a cross-sectional view of the solar cell taken along the II-II line of FIG. 1; and

FIG. 3 is a graph of current densities as functions of voltages for solar cells according to Examples 1 and 2 and Comparative Example.

### DETAILED DESCRIPTION OF THE EMBODIMENTS

Reference will now be made in detail to the present embodiments of the present invention, examples of which are illustrated in the accompanying drawings, wherein like reference numerals refer to the like elements throughout. The embodiments are described below in order to explain the present invention by referring to the figures.

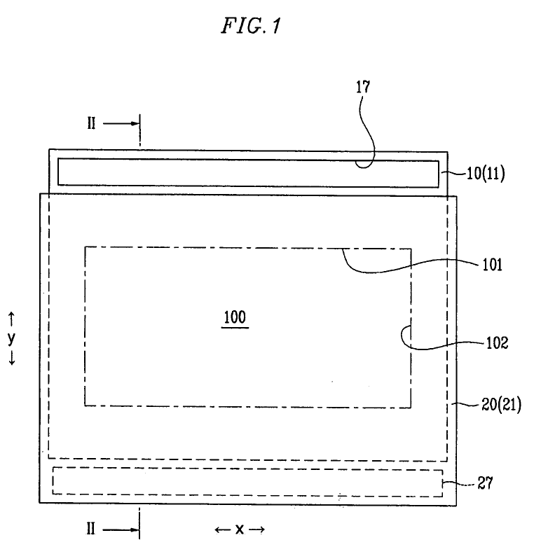

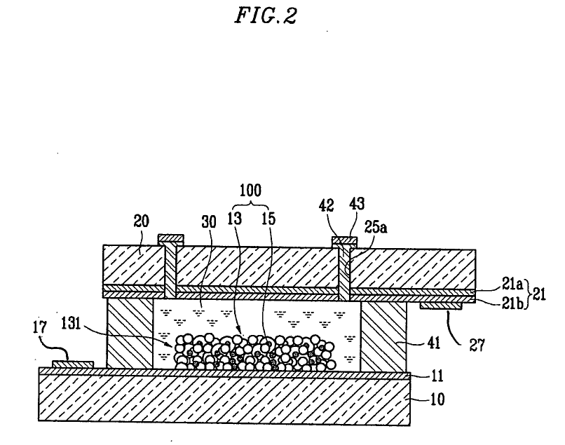

FIG. 1 is a plan view of a solar cell according to an embodiment of the present invention, and FIG. 2 is a cross-sectional view of the solar cell taken along the II-II line of FIG. 1.

As shown in FIGS. 1 and 2, the solar cell according to the present embodiment includes a first substrate 10, and a second substrate 20 that is attached to the first substrate 10 with an adhesive 41. The first substrate 10 includes a first electrode 11, a porous film 13 including an adsorbed dye 15, and a first lead electrode 17. The second substrate 20 includes a second electrode 21 and a second lead electrode 27. An electrolyte 30 is disposed between the first and second electrodes 11 and 21.

The porous film 13 and the dye 15 adsorbed on the porous film 13 may be collectively called a light absorption layer 100. The light absorption layer 100 generates electrons upon receipt of light incident thereupon, and transfers the electrons to the first electrode 11.

In the particular embodiment described herein, the first substrate 10 supports the first electrode 11, and is formed with a transparent material to pass external light therethrough. The first substrate 10 may be formed of transparent glass or plastic. The plastic may be selected from polyethylene terephthalate (PET), polyethylene naphthalate (PEN), polycarbonate (PC), polypropylene (PP), polyimide (PI), and triacetyl cellulose (TAC). The first substrate 10 is not limited to these materials, and other materials are possible.

The first electrode 11 provided on the first substrate 10 may be formed with a transparent material, such as indium tin oxide (ITO), fluorine tin oxide (FTO), antimony tin oxide (ATO), zinc oxide, tin oxide, ZnO—Ga₂O₃, and ZnO—Al₂O₃. The first electrode 11 is not limited to these materials, and other materials are possible. The first electrode 11 may be formed with a transparent material-based single layer structure or a laminated layer structure.

In the particular embodiment described herein, the first substrate 10 and the first electrode 11 are formed in the shape of a rectangle. That is, the first electrode 11 has a long edge proceeding in a first direction (in the direction of the x axis of the drawing), and a short edge proceeding in a second direction (in the direction of the y axis of the drawing) crossing the first direction.

A porous film 13 containing metallic oxide particles 131 is formed on the first electrode 11. The metallic oxide particles 131 may be formed with titanium oxide, zinc oxide, tin oxide, strontium oxide, indium oxide, iridium oxide, lanthanum oxide, vanadium oxide, molybdenum oxide, tungsten oxide, niobium oxide, magnesium oxide, aluminum oxide, yttrium oxide, scandium oxide, samarium oxide, gallium oxide, or strontium titanium oxide. It is preferable that the metallic oxide particles 131 are formed with titanium oxide (TiO₂), tin oxide (SnO₂), tungsten oxide (WO₃), zinc oxide (ZnO), or a combination thereof. The metallic oxide particles 131 are not limited to these materials, and other materials are possible.

In order to enhance the performance characteristics of the porous film 13, conductive micro-particles (not shown) and light-scattering particles (not shown) may be added to the porous film 13.

The conductive micro-particles added to the porous film 13 may enhance the mobility of the excited electrons. For instance, the conductive micro-particles may be based on indium tin oxide. The light-scattering particles added to the porous film 13 extend the optical path within the solar cell to thereby enhance the photoelectric conversion efficiency thereof. The light-scattering particles may be formed with the same material as the porous film 13, although other materials are possible. The light-scattering particles preferably, but not necessarily, have a mean particle diameter of 100 nm or more to effectively cause the light to scatter.

The dye 15 is adsorbed onto the surface of the metallic oxide particles 131 of the porous film 13 to absorb external light and generate excited electrons. The dye 15 may be formed with a metal complex containing aluminum (Al), platinum (Pt), palladium (Pd), europium (Eu), lead (Pb), iridium (Ir), or ruthenium (Ru). As ruthenium, which belongs to the platinum group, is capable of forming many organic metal complexes, a ruthenium-containing dye is commonly used. Furthermore, an organic dye selected from coumarin, porphyrin, xanthene, riboflavin, and triphenylmethane may also be used. The dye 15 is not limited to these materials, and other materials are possible.

The first lead electrode 17 is formed along the long edge of the first electrode 11 close thereto while being spaced apart from the dye-adsorbed porous film 13, that is, from the light absorption layer 100. The first lead electrode 17 may be placed external to the adhesive 41 that attaches the first and second substrates 10 and 20 to each other. The first lead electrode 17 is connected to an external circuit (not shown).

In the embodiment described herein, the light absorption layer 100 has an optimized structure such that the electrons generated from the light absorption layer 100 easily migrate to the first lead electrode 17 via the first electrode 11. This structure will be specifically explained later.

The second substrate 20 facing the first substrate 10 supports the second electrode 21, and is formed with a transparent material. As with the first substrate 10, the second substrate 20 may be formed with a transparent glass or plastic. The plastic may be selected from polyethylene terephthalate, polyethylene naphthalate, polycarbonate, polypropylene, polyimide, and triacetyl cellulose. The second substrate 20 is not limited to these materials, and other materials are possible.

The second electrode 21 formed on the second substrate 20 faces the first electrode 11, and has a transparent electrode 21a and a catalyst electrode 21b. The transparent electrode 21a may be formed with a transparent material such as indium tin oxide, fluorine tin oxide, antimony tin oxide, zinc oxide, tin oxide, ZnO—Ga_{2O}₃, and ZnO—Al₂O₃. The transparent electrode 21a is not limited to these materials, and other materials are possible. The transparent electrode 21a may be formed with a single layer structure based on the transparent material or a laminated layer structure. The catalyst electrode 21b activates the redox couple, and may be formed with platinum (Pt), ruthenium (Pd), palladium (Pd), iridium (Ir), rhodium (Rh), osmium (Os), carbon (C), tungsten oxide (WO₃), or titanium oxide (TiO₂). The catalyst electrode 21b is not limited to these materials, and other materials are possible.

In the embodiment described herein, the second substrate 20 and the second electrode 21 are formed in the shape of a rectangle. That is, the second electrode 21 has a long edge proceeding in a first direction (in the direction of the x axis of the drawing), and a short edge proceeding in a second direction (in the direction of the y axis of the drawing) crossing the first direction.

The second lead electrode 27 is formed along the long edge of the second electrode 21 close thereto such that it is placed opposite to the first lead electrode 17. The second lead electrode 27 may be located external to the adhesive 41. The second lead electrode 27 is connected to an external circuit (not shown).

An electrolyte 30 is injected into the interior between the first and second electrodes 11 and 21 through holes 25a formed at the second substrate 20 and the second electrode 21. The electrolyte 30 is uniformly diffused into the light absorption layer 100. The electrolyte 30 receives and transfers electrons from the second electrode 21 to the dye 15 through reduction and oxidation. As a non-limiting example, the electrolyte may be an iodide-containing electrolyte. As a further non-limiting example, the electrolyte may comprise tetrapropylammonium iodide and iodine (I₂) in a solvent mixture of ethylene carbonate and acetonitrile. The holes 25a formed at the second substrate 20 and the second electrode 21 are sealed with an adhesive 42 and a cover glass 43. The electrolyte 30 is not limited to a liquid electrolyte as described herein. For example, the electrolyte 30 may be a gel or solid electrolyte.

When external light such as sunlight hits the interior of the solar cell, photons are absorbed into the dye so that the dye is shifted from a ground state to an excited state, thereby generating electrons. The excited electrons migrate into the conduction bands of the metallic oxide particles 131 of the porous film 13, and flow to an external circuit (not shown) through the first electrode 11 and the first lead electrode 17. Thereafter, the electrons are transferred to the second lead electrode 27 and the second electrode 21. Meanwhile, if an iodide-containing electrolyte is used, the iodide within the electrolyte 50 is oxidized into triiodide and the dye 15 that was oxidized by the transfer of electrons in response to the external light is reduced to its original state. The triiodide reacts with the electrons that have reached the second electrode 21 and is thereby reduced back into iodide. The solar cell therefore operates due to the migration of electrons.

As the region of the light absorption layer 100 absorbs external light and generates excited electrons to transfer to the first electrode 11, with the embodiment described herein, the design of the light absorption layer 100 is optimized to allow the electrons to migrate easily.

That is, in the embodiment described herein, the value of A is established to be larger than the value of B, wherein A is the length of a first edge 101 of the light absorption layer 100 proceeding in a first direction alongside or parallel the first lead electrode 17, and B the length of a second edge 102 of the light absorption layer 100 proceeding in a second direction, which may be transverse to the first direction.

Without changing the area of the light absorption layer 100, the first edge 101 of the light absorption layer 100 facing the first lead electrode 17 may be elongated, thereby increasing the length of the interface between the first lead electrode 17 and the light absorption layer 100 (The second edge 102 may proportionately truncated so that the same area for the light absorption layer 100 is maintained). Accordingly, the electrons migrate from the light absorption layer 100 to the first lead electrode 17 through the first electrode 11 with a wider area, thereby reducing the movement distance and time thereof.

Furthermore, when the second edge 102 of the light absorption layer 100 is shortened, electrons that are generated and migrate from the light absorption layer 100 through the first electrode 11 to the first lead electrode 17 may move with reduced distance and time.

Therefore, the amount of electrons generated from the light absorption layer 100 and that migrate to the first lead electrode 17 through the first electrode 11 is increased, while the movement time of the electrons is decreased. Consequently, current collecting is maximized, and the time required for the current collecting is minimized. In this way, the photoelectric conversion efficiency of the solar cell is enhanced.

As an example, the light absorption layer 100 may satisfy the following Formula 1:
1.3≦A/B<125 (1),
wherein A and B are as defined above.

If the value of A/B is less than 1.3, the current collecting effect is inferior. On the other hand, if the value of A/B exceeds 125, it is difficult to form the light absorption layer 100.

Considering the formation conditions of the light absorption layer 100, it is preferable, but not necessary that the light absorption layer 100 satisfy the following condition:
1.3≦A/B≦5 (2).

Provided that the absolute area of the light absorption layer 100 serving to generate electrons has a predetermined value, the conditions of the Formulas 1 and 2 may be significant. In this consideration, it is preferable, but not necessary, that the first electrode 11 and the light absorption layer 100 satisfy the following Formula 3:
0.05≦C≦1 (3),
where C is the ratio of the area of the light absorption layer 100 to the area of the first electrode 11.

Although in the embodiment shown in FIG. 1, the light absorption layer 100 is depicted as a rectangle, the light absorption layer 100 is not limited to this shape, and other shapes are possible, such as, for example, trapezoidal or shapes that do not have straight edges. Accordingly, the light absorption layer 100 may satisfy the following Formula 4:
1.3≦D/E≦125 (4),
wherein D is the greatest length of the light absorption layer 100 in a direction parallel to the direction of the first lead electrode 17 and E is the greatest length of the light absorption layer 100 is a direction orthogonal to D. The light absorption layer 100 may be formed so an edge of the light absorption layer 100 that is closest to the first lead electrode 17 has the length D. Thus, if the light absorption layer 100 is a rectangle, then A/B as defined for formula (1) equals D/E as defined for formula (4). But if the light absorption layer 100 is not a rectangle, then it is still possible according to formula (4) to determine if the light absorption layer 100 has a topography that provides enhanced current collecting.

A solar cell according to aspects of the present invention will be now specifically explained by way of examples. The examples are given only to illustrate aspects of the present invention, but are not intended to limit the scope of the invention.

### EXAMPLE 1

A first electrode was formed on a first substrate based on glass with a size of 3 cm×1 cm, with niobium tin oxide. The first electrode was heat-treated at 500° C. for 30 minutes such that the first electrode had a resistivity of 8 Ω/sq. A conductive tape was attached to the first electrode along the long edge thereof to thereby form a first lead electrode.

A paste in which TiO₂ particles were diffused in a solvent was prepared, and coated with a doctor blade onto the first electrode at a thickness of 15 μm, and the paste was fired at 450° C. for 30 minutes to thereby form a porous film on the first electrode.

The first substrate with the first electrode and the porous film was dipped in 0.3 mM of a solution of ruthenium(4,4-dicarboxy-2,2′-bipyridine)₂ (NCS)₂ for 24 hours, thereby adsorbing the dye into the porous film and forming a light absorption layer. The length of the first edge of the light absorption layer facing the first lead electrode was 2 cm, and the length of the second edge of the light absorption layer crossing the first edge was 0.1 cm. The light absorption layer was cleaned using ethanol, and dried at ambient temperature.

Indium tin oxide and platinum were sequentially deposited onto a second substrate based on glass with a size of 3 cm×1 cm to thereby form a second electrode. Breakthrough holes were formed at the second substrate and the second electrode using a drill with a diameter of 0.75 m. A conductive tape was attached to the long edge of the second substrate to thereby form a second lead electrode.

The first and second substrates were arranged such that the porous film formed on the first substrate faced the second electrode. A thermoplastic polymer film with a thickness of 60 μm was placed between the first and second electrodes as an adhesive, and thermally pressed at 100° C. for 9 seconds to thereby attach the first and second substrates to each other. The first and second lead electrodes were located external to the adhesive such that they could be connected to external circuits.

An electrolyte was injected into the interior between the first and second substrates through the holes of the second substrate and the second electrode, and the holes were sealed using a thermoplastic polymer film and a cover glass, thereby completing a solar cell. The electrolyte was a solution formed by dissolving 21.928 g of tetrapropylammonium iodide and 1.931 g of iodine (12) in 100 ml of a solvent mixture comprising 80 vol % of ethylene carbonate and 20 vol % of acetonitrile.

### EXAMPLE 2

A solar cell was manufactured in the same way as in Example 1 except that the first substrate was formed of glass with a size of 2 cm×1 cm, and the length of the first edge of the light absorption layer was 1 cm while the length of the second edge of the light absorption layer crossing the first edge was 0.2cm.

### COMPARATIVE EXAMPLE

A solar cell was manufactured in the same way as in Example 1 except that the first substrate was formed with glass with a size of 1.5 cm×1.5 cm, and the length of the first edge of the light absorption layer was 0.5 cm while the length of the second edge of the light absorption layer crossing the first edge was 0.4 cm.

In sum, in Examples 1 and 2 and the Comparative Example, the light absorption layers all had the same area, 0.2 cm². The difference was that the length ratio of the first edge of the light absorption layer to the second edge of the light absorption layer, that is, the value of A/B, was 20 with Example 1, 5 with Example 2, and 1.25 with the Comparative Example.

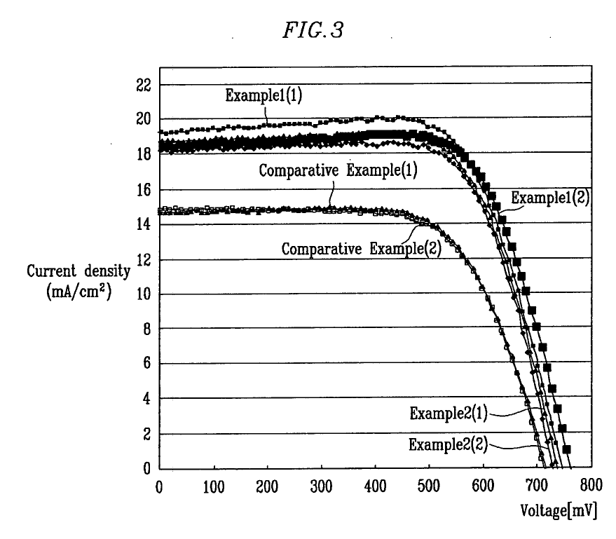

The current densities as functions of voltages of the solar cells according to the Examples 1 and 2 and the Comparative Example were measured two times using a light source of 100 mW/cm², and the results are shown in FIG. 3. The data from FIG. 3 are summarized and listed in Table 1.

| | Short circuit | | | |
|---|---|---|---|---|
| | current density | Open circuit | Fill | Efficiency |
| | (mA/cm²) | voltage (V) | factor | (%) |
| Ex. 1 (1^{st} trial) | 19.25 | 0.75 | 0.71 | 10.16 |
| Ex. 1 (2^{nd} trial) | 18.53 | 0.76 | 0.71 | 10.06 |
| Ex. 2 (1^{st} trial) | 18.74 | 0.74 | 0.70 | 9.68 |
| Ex. 2 (2^{nd} trial) | 18.00 | 0.76 | 0.71 | 9.69 |
| Com. Ex. (1^{st} trial) | 14.84 | 0.71 | 0.66 | 7.00 |
| Com. Ex. (2^{nd} trial) | 14.72 | 0.72 | 0.67 | 7.09 |

As can be calculated from Table 1, the average value of the short circuit current density in Example 1 was 18.89 mA/cm², the average value of the short circuit current density of Example 2 was 18.37 mA/cm², and the average value of the short circuit current density in Comparative Example was 14.78 mA/cm². That is, the average value of the short circuit current density in the Examples was much higher than that in the Comparative Example. This was because the length ratio of the edges of the light absorption layer was optimized with Examples 1 and 2, so that even though the area of the light absorption layers of Examples 1 and 2 was the same as that of the light absorption layer of Comparative Example, the mobility of the electrons was reinforced in the light absorption layers of Examples 1 and 2 so that the electric current could be increased. Specifically, the light absorption layer and the first lead electrode faced each other with a larger area of interaction, and the movement distance of electrons from the light absorption layer to the first lead electrode was shortened so that the electrons could flow more easily.

Furthermore, the average value for efficiency was 10.1% in Example 1, 9.68% in Example 2, and 7.04% in the Comparative Example. That is, the average values for efficiency in the Examples 1 and 2 were very much higher than that of the Comparative Example. With Examples 1 and 2, it is believed that the efficiency was enhanced because of the increase in short circuit current density.

In the embodiment described herein, a solar cell with a light absorption layer having a dye and a porous film is exemplified as a solar cell, but the present invention is not limited thereto. That is, the inventive structure may be applied to other types of solar cells, and other types of solar cells having a light absorption layer with the dimensional relationships described herein are also within the scope of the present invention.

As described above, with the solar cell according to aspects of the embodiment of the present invention, the length ratio of the edges of the light absorption layer is optimized to thereby increase the length of the edge that faces the first lead electrode such that electrons can flow more easily to the first lead electrode. Furthermore, the average movement distance of electrons is reduced to thereby minimize the time required for current collecting. Consequently, the collection of electrons is maximized, thereby effectively enhancing the photoelectric conversion efficiency.

Furthermore, the first electrode is structured such that one side edge thereof is longer than the other side edge, and the first lead electrode is formed along the long edge, thereby duplicating the efficiency enhancement effect.

Although a few embodiments of the present invention have been shown and described, it would be appreciated by those skilled in the art that changes may be made in this embodiment without departing from the principles and spirit of the invention, the scope of which is defined in the claims and their equivalents.

What is claimed is:

1. A solar cell comprising:
first and second electrodes facing each other;
a light absorption layer formed on the first electrode, wherein the light absorption layer has a first edge proceeding in a first direction and a second edge proceeding in a second direction crossing the first direction; and
a lead electrode formed on the first electrode in the first direction such that the lead electrode is spaced apart from the light absorption layer,
wherein when the length of the first edge of the light absorption layer proceeding in the first direction is indicated by A and the length of the second edge of the light absorption layer proceeding in the second direction crossing the first direction is indicated by B, the value of A/B satisfies the following condition:
1.3≦A/B≦125.

2. The solar cell of claim 1, wherein the value of A/B satisfies the following condition:
1.3≦A/B≦5.

3. The solar cell of claim 1, wherein, when an area ratio of the light absorption layer to the first electrode is indicated by C, the value of C satisfies the following condition:
0.05≦C≦1.

4. The solar cell of claim 1, wherein the lead electrode is placed adjacent to an edge of the first electrode.

5. The solar cell of claim 1, wherein the lead electrode is placed adjacent to a long edge of the first electrode.

6. The solar cell of claim 1, wherein an edge of the first electrode proceeding in the first direction is longer than an edge of the first electrode proceeding in the second direction.

7. The solar cell of claim 1, wherein an edge of the second electrode proceeding in the first direction is longer than an edge of the second electrode proceeding in the second direction.

8. The solar cell of claim 7, further comprising a lead electrode formed on the second electrode in the first direction.

9. The solar cell of claim 1, wherein the light absorption layer comprises a porous film having a dye adsorbed thereon.

10. The solar cell of claim 1, wherein the porous film comprises metal oxide particles.

11. The solar cell of claim 1, wherein the light absorption layer further comprises conductive micro-particles and light-scattering particles.

12. The solar cell of claim 1, further comprising a first substrate supporting the first electrode and a second substrate supporting the second electrode and wherein the first and second substrates independently comprise transparent glass or a plastic selected from polyethylene terephthalate (PET), polyethylene naphthalate (PEN), polycarbonate (PC), polypropylene (PP), polyimide (PI), and triacetyl cellulose (TAC).

13. The solar cell of claim 1, wherein first electrodes comprises indium tin oxide (ITO), fluorine tin oxide (FTO), antimony tin oxide (ATO), zinc oxide, tin oxide, ZnO—Ga₂O₃, or ZnO—Al₂O₃.

14. The solar cell of claim 1, wherein the second electrode comprises a transparent electrode comprising indium tin oxide (ITO), fluorine tin oxide (FTO), antimony tin oxide (ATO), zinc oxide, tin oxide, ZnO—Ga₂O₃, or ZnO—Al₂O₃ and a catalyst electrode comprising platinum (Pt), ruthenium (Pd), palladium (Pd), iridium (Ir), rhodium (Rh), osmium (Os), carbon (C), tungsten oxide (WO₃), or titanium oxide (TiO₂).

15. The solar cell of claim 1, further comprising an electrolyte comprising tetrapropylammonium iodide and iodine (I₂) in a solvent mixture of ethylene carbonate and acetonitrile

16. A solar cell comprising:
first and second electrodes facing each other;
a light absorption layer formed on the first electrode; and
a lead electrode formed on the first electrode in a first direction such that the lead electrode is spaced apart from the light absorption layer,
wherein when the greatest length of the light absorption layer in a direction parallel to the first direction of the lead electrode is indicated by D and the greatest length of the light absorption layer in the second direction orthogonal to the first direction is indicated by E, the value of D/E satisfies the following condition:
1.3≦D/E≦125.

17. The solar cell of claim 1, wherein the value of D/E satisfies the following condition:
1.3≦D/E≦5.

18. The solar cell of claim 1, wherein, when an area ratio of the light absorption layer to the first electrode is indicated by C, the value of C satisfies the following condition:
0.05≦C≦1.
